(19) United States
(12) Patent Application Publication
(10) Pub. No.: US 2009/0190118 A1
(43) Pub. Date: Jul. 30, 2009

(54) EXPOSURE APPARATUS INSPECTION MASK, AND METHOD OF INSPECTING EXPOSURE APPARATUS USING EXPOSURE APPARATUS INSPECTION MASK

(76) Inventor: Kazuya FUKUHARA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/358,519

(22) Filed: Jan. 23, 2009

(30) Foreign Application Priority Data
Jan. 28, 2008 (JP) 2008-16063

(51) Int. Cl. G03B 27/32; G03F 1/00

(52) U.S. Cl. 355/77; 430/5

(57) ABSTRACT

An exposure apparatus inspection mask has asymmetric diffraction grating regions for generating +1-order diffracted light and −1-order diffracted light having a different diffraction efficiency. The asymmetric diffraction grating region includes: a transparent substrate; semi-transparent phase shifter films selectively and periodically disposed on the transparent substrate at a predetermined pitch; and shade films selectively and periodically disposed on the phase shifter films at a predetermined pitch. The phase shifter films are formed to have such a thickness that the phase difference between the phase of first light passing through only the transparent substrate and the phase of second light passing through the phase shifter films and the transparent substrate is set to a value other than 180°×n (n is an integer equal to or larger than 0).

### CROSS-REFERENCE TO RELATED APPLICATIONS

This application is based upon and claims the benefit of priority from the prior Japanese Patent Application No. 2008-16063, filed on Jan. 28, 2008, the entire contents of which are incorporated herein by reference.

### BACKGROUND OF THE INVENTION

1. Field of the Invention

The present invention relates to an exposure apparatus inspection mask used in a semiconductor lithography process, and a method of inspecting an exposure apparatus using the exposure apparatus inspection mask.

2. Description of the Related Art

When a fine resist pattern is formed using a projection exposure apparatus (stepper) in an optical lithography step of a semiconductor manufacturing process, the state of an optical system of the exposure apparatus, particularly the focus position of the exposure apparatus must be set to a suitable state on a substrate. When the focus position of the exposure apparatus is not set to the suitable position on the substrate, a so-called out-of-focus state occurs and it is difficult to form a desired fine pattern. In particular, recently, since a transfer pattern has been more miniaturized, it is very important to accurately set a focus position of an exposure apparatus.

Accordingly, various technologies such as a technology of accurately monitoring a focus position of an exposure apparatus from an exposed pattern formed by, for example, exposure, and the like have been developed as a method of accurately aligning the focus position on the substrate.

For example, Japanese Patent Application Laid-Open No. 2002-55435 proposes a method of measuring a focus error of an exposure apparatus using diffraction gratings (focus marks) having a different intensity between a positive diffracted light and a negative diffracted light, and an asymmetric diffraction efficiency.

Japanese Patent Application Laid-Open No. 2002-55435 describes a so-called engraving-type phase shift film in which a phase shift region is formed by engraving a photo mask substrate. In contrast, photo masks generally used for manufacturing semiconductor devices often employ amplitude modulation type phase shift masks, i.e., so-called attenuated type phase shift masks. Further, Japanese Patent Application Laid-Open No. 2005-70672 proposes a method of disposing an attenuated type phase shift mask and a focus monitor on the same mask.

Formation of the attenuated type phase shift mask and the engraving type phase shift film on the same mask as shown in Japanese Patent Application Laid-Open Nos. 2002-55435 and 2005-70672 increases the number of steps of a photo mask manufacturing process and the cost of a photo mask.

Further, when the masks disclosed in Japanese Patent Application Laid-Open Nos. 2002-55435 and 2005-70672 are manufactured, it is necessary to expose the mask by illumination light which is vertically incident thereon. Generally, an exposure apparatus used to manufacture a semiconductor device employs obliquely incident illumination such as quadrupole illumination. Accordingly, an exposure step for manufacturing a semiconductor device and a step of setting a focus position by a focus mark must be performed with different illumination lights. Thus, it is time-consuming or cumbersome to accurately specify the focus position. Additionally, aberration on the projector lens may sometimes make a focus position to be out of alignment, depending on an illumination condition. Accordingly, it's preferable to perform the exposure step for manufacturing a semiconductor device and the step of setting a focus position by a focus mark on the same illumination condition.

### BRIEF SUMMARY OF THE INVENTION

A first exposure apparatus inspection mask according to one aspect of the present invention has asymmetric diffraction grating regions for generating +1-order diffracted light and −1-order diffracted light having a different diffraction efficiency, each of the asymmetric diffraction grating regions comprising: a transparent substrate; semi-transparent phase shifter films selectively and periodically disposed on the transparent substrate at a predetermined pitch; and shade films selectively and periodically disposed on the phase shifter films at a predetermined pitch, the phase shifter films being formed to have such a thickness that a phase difference between a phase of first light passing through only the transparent substrate and a phase of second light passing through the phase shifter films and the transparent substrate is set to a value other than 180°×n (n is an integer equal to or larger than 0).

According to one aspect of the present invention, there is provided a method of inspecting an exposure apparatus using an exposure apparatus inspection mask having device pattern regions used to expose a device pattern and asymmetric diffraction grating regions for generating +1-order diffracted light and −1-order diffracted light having a different diffraction efficiency, each region being disposed on a transparent substrate, the method comprising: exposing the device pattern regions and the asymmetric diffraction grating regions and projecting them onto a substrate; imaging focus patterns obtained by exposing the asymmetric diffraction grating regions projected onto the substrate; obtaining information as to the state of a projection optical system for projecting light to the substrate based on the imaged focus pattern; and correcting the state of the projection optical system based on the information, in projecting the substrate, radiating obliquely incident light to the exposure apparatus inspection mask from a direction offset by a first angle from a vertical direction.

A first exposure apparatus inspection mask according to one aspect of the present invention has asymmetric diffraction grating regions for generating +1-order diffracted light and −1-order diffracted light having a different diffraction efficiency, each of the asymmetric diffraction grating regions comprising: a reflecting substrate; phase shifter films selectively and periodically disposed on the reflecting substrate at a predetermined pitch, having reflectivity to irradiated light which is lower than one of the reflecting substrate; and absorption films selectively and periodically disposed on the phase shifter films at a predetermined pitch, and the phase shifter films are formed to have such a thickness that a phase difference between a phase of first light reflecting only the reflecting substrate and a phase of second light reflecting only the phase shifter films is set to a value other than 180°×n (n is an integer equal to or larger than 0).

### BRIEF DESCRIPTION OF THE DRAWINGS

FIG. 1 is a schematic view of a configuration of an exposure apparatus 10 according to a first embodiment of the present invention;

FIG. 2 is a schematic view of an upper surface of an inspection mask 20 of the exposure apparatus 10 according to the first embodiment of the present invention;

FIG. 3 is a partially enlarged view of FIG. 2;

FIG. 4 is a schematic side elevational view of the inspection mask 20 of the exposure apparatus 10 according to the first embodiment of the present invention;

FIG. 5A is a view explaining a distribution of light radiated to an illumination optical system 13 and a projection optical system 15 of the exposure apparatus 10 and light diffracted by the inspection mask 20 according to the first embodiment of the present invention;

FIG. 5B is a view explaining a distribution of light radiated to an illumination optical system 13 and a projection optical system 15 of an exposure apparatus 10a and light diffracted by the inspection mask 20 according to the first embodiment of the present invention;

FIG. 5C is a view explaining a method of determining the radius and the center of an illumination pole in a secondary light source surface 13a of the present invention;

FIG. 6 is a view explaining an outline of focus patterns projected on a wafer W of the exposure apparatus 10 according to the first embodiment of the present invention;

FIG. 7 is a view explaining an outline of focus patterns projected on the wafer W of the exposure apparatus 10 according to the first embodiment of the present invention;

FIG. 8 is a view showing a result calculated by simulating a relative distance δx to a focus offset amount δf in the exposure apparatus 10 according to the first embodiment of the present invention;

FIG. 9 is a view showing a manufacturing step of the inspection mask 20 in the exposure apparatus 10 according to the first embodiment;

FIG. 10 is a view showing a manufacturing step of the inspection mask 20 in the exposure apparatus 10 according to the first embodiment;

FIG. 11 is a view showing a manufacturing step of the inspection mask 20 in the exposure apparatus 10 according to the first embodiment;

FIG. 12 is a view showing a manufacturing step of the inspection mask 20 in the exposure apparatus 10 according to the first embodiment;

FIG. 13 is a view showing a manufacturing step of the inspection mask 20 in the exposure apparatus 10 according to the first embodiment;

FIG. 14 is a view showing a manufacturing step of the inspection mask 20 in the exposure apparatus 10 according to the first embodiment;

FIG. 15 is a view showing a manufacturing step of the inspection mask 20 in the exposure apparatus 10 according to the first embodiment;

FIG. 16 is a schematic upper surface view of an inspection mask 20a of an exposure apparatus according to a second embodiment of the present invention;

FIG. 17 is a sectional view of the inspection mask 20a of the exposure apparatus according to the second embodiment of the present invention;

FIG. 18 is an enlarged view of a part A of FIG. 16;

FIG. 19 is a view explaining configurations of a first inner mark IM1 and a first outer mark OM1 of the inspection mask 20a according to the second embodiment of the present invention;

FIG. 20 is a view explaining configurations of a second inner mark IM2 and a second outer mark OM2 of the inspection mask 20a according to the second embodiment of the present invention;

FIG. 21 is a flowchart explaining an operation of the exposure apparatus according to the second embodiment of the present invention;

FIG. 22 is a view showing a manufacturing step of the inspection mask 20a according to the second embodiment;

FIG. 23 is a view showing a manufacturing step of the inspection mask 20a according to the second embodiment;

FIG. 24 is a view showing a manufacturing step of the inspection mask 20a according to the second embodiment;

FIG. 25 is a view showing a manufacturing step of the inspection mask 20a according to the second embodiment;

FIG. 26 is a view showing a manufacturing step of the inspection mask 20a according to the second embodiment;

FIG. 27 is a view showing a manufacturing step of the inspection mask 20a according to the second embodiment;

FIG. 28 is a view showing a manufacturing step of the inspection mask 20a according to the second embodiment;

FIG. 29 is a schematic view of a configuration of an exposure apparatus 10a according to a third embodiment of the present invention; and

FIG. 30 is a view showing an illumination pole in a secondary light source surface 13c of an illumination optical system of an exposure apparatus according to another embodiment of the present invention.

### DETAILED DESCRIPTION OF THE EMBODIMENTS

An exposure apparatus inspection mask, and a method of inspecting an exposure apparatus using the exposure apparatus inspection mask according to the present invention will be explained below referring to the drawings.

### First Embodiment

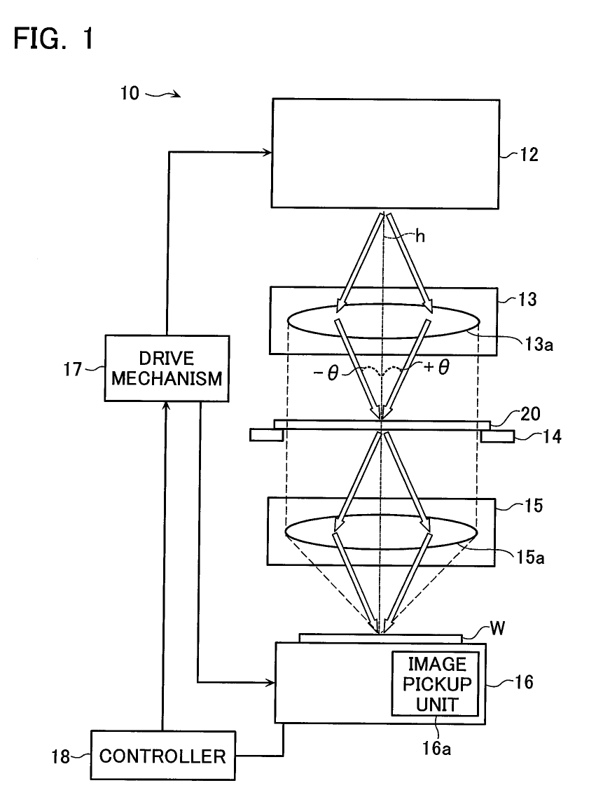

First, an exposure apparatus 10 according to a first embodiment of the present invention will be explained referring to FIG. 1. FIG. 1 shows a schematic view of the exposure apparatus 10 according to the first embodiment of the present invention. As shown in FIG. 1, the exposure apparatus 10 according to the first embodiment mainly includes a light source optical system 12, an illumination optical system 13, a photo mask stage 14, a projection optical system 15, a wafer stage 16, a drive mechanism 17, and a controller 18.

The light source optical system 12 has a light source. The light source optical system 12 is configured to radiate obliquely incident light beams to two positions of a secondary light source surface 13a of the illumination optical system 13 from different directions. In other words, the light source optical system 12 is configured to radiate dipole lights to the secondary light source surface 13a.

The illumination lights passed through the illumination optical system 13 reaches the wafer stage 16 about an optical axis h through the photo mask stage 14 and the projection optical system 15.

The photo mask stage 14 is configured so that a photo mask, which has an exposure pattern used to expose a wafer W, and a photo mask, which has an inspection pattern used to inspect the states of the illumination optical system 13 and the projection optical system 15, can be placed thereon. Further, a photo mask having both an exposure pattern and an inspection pattern can be also placed on the photo mask stage 14. Hereinafter, the photo mask having the inspection pattern is called an inspection mask 20.

The wafer stage 16 is configured so that the wafer W can be placed thereon. Further, an image pickup unit (CCD camera or the like) 16a is disposed on the wafer stage 16 to image or pick up a focus pattern (image) focused on the wafer W.

The drive mechanism 17 is configured to move the wafer stage 16 forward and rearward with respect to an exposure light source 11. Further, the drive mechanism 17 is configured so that it can move the wafer stage 16 up to a position away from the optical axis h.

The controller 18 is configured to calculate the focus offset of the projection optical system 15 based on the focus pattern picked up by the image pickup unit 16a. The controller 18 is configured to control the drive of the drive mechanism 17 based on the focus pattern by the inspection mask 20.

In the exposure apparatus 10, the illumination optical system 13 is formed so that it radiates lights having a wavelength of, for example, 193 nm and the projection optical system 15 has an NA value of 0.85 in correspondence to the lights.

Further, the exposure apparatus 10 according to the first embodiment is configured so that it satisfies the following three conditions:

(1) One of ±1-order diffracted lights passed through the inspection mask 20 is extinguished;

(2) Only two fluxes of lights among the diffracted lights passed through the inspection mask 20 pass through a pupil 15a of the projection optical system 15; and

(3) 0-order diffracted light and +1-order diffracted light (or −1-order diffracted light) passed through the inspection mask 20 are asymmetrically radiated to the pupil 15a of the projection optical system 15.

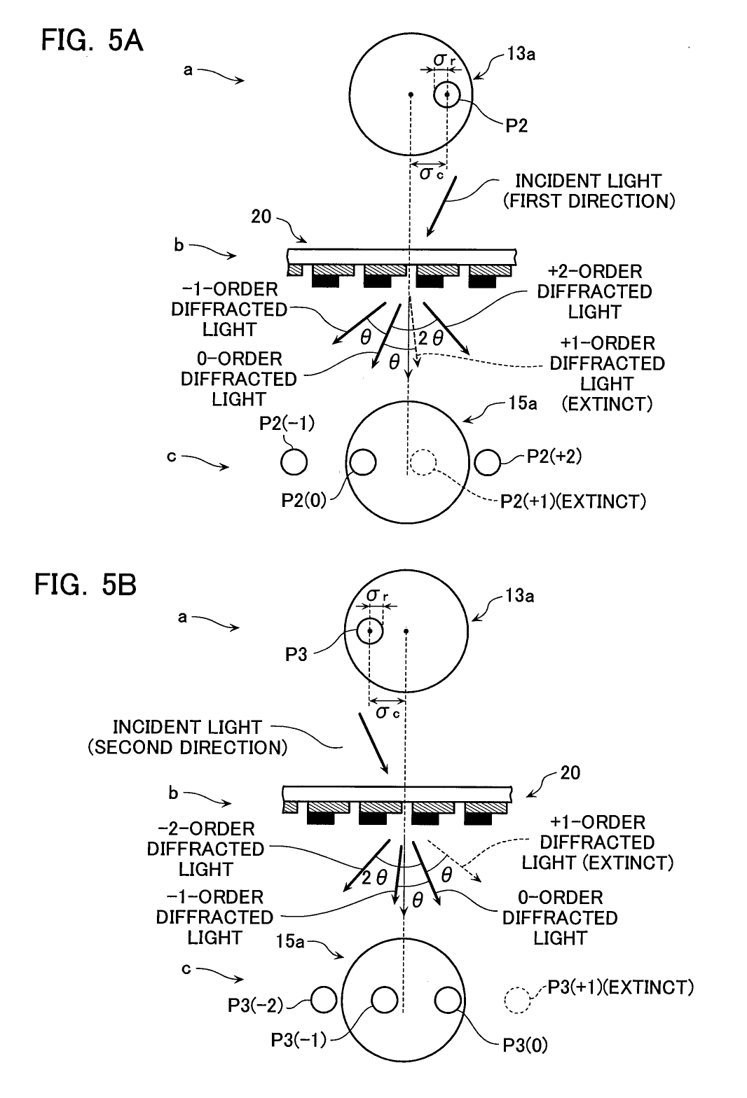

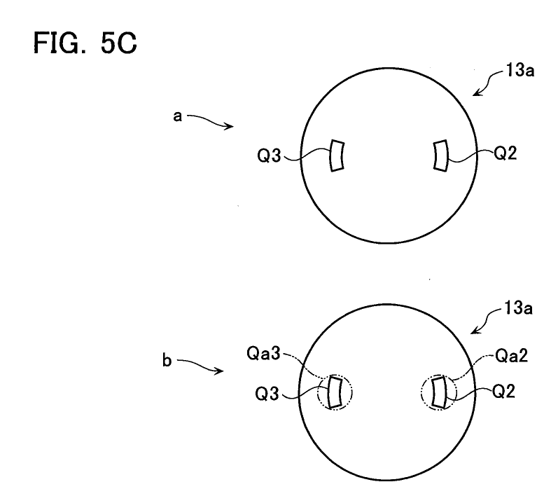

The above condition is shown by the following expression 1 when an exposure wavelength is shown by λ, a numerical aperture of the projection optical system 15 is shown by NA, the pitch of the inspection mask 20 is shown by p (refer to FIG. 3), the distance from the center of the secondary light source surface 13a of the illumination optical system 13 to the center of an illumination pole (region to which lights are radiated) is shown by σ_{c} (refer to a symbol “a” of FIG. 5A or a symbol “a” of FIG. 5B to be described later), and a radius of the illumination pole is shown by σᵣ (refer to the symbol “a” of FIG. 5A or the symbol “a” of FIG. 5B to be described later).

### (Expression 1)

$$\frac{λ}{2 {σ}_{c} \cdot NA} < p < \frac{2 λ}{NA ( {σ}_{c} + {σ}_{r} + 1 )} \qquad ( 1 )$$

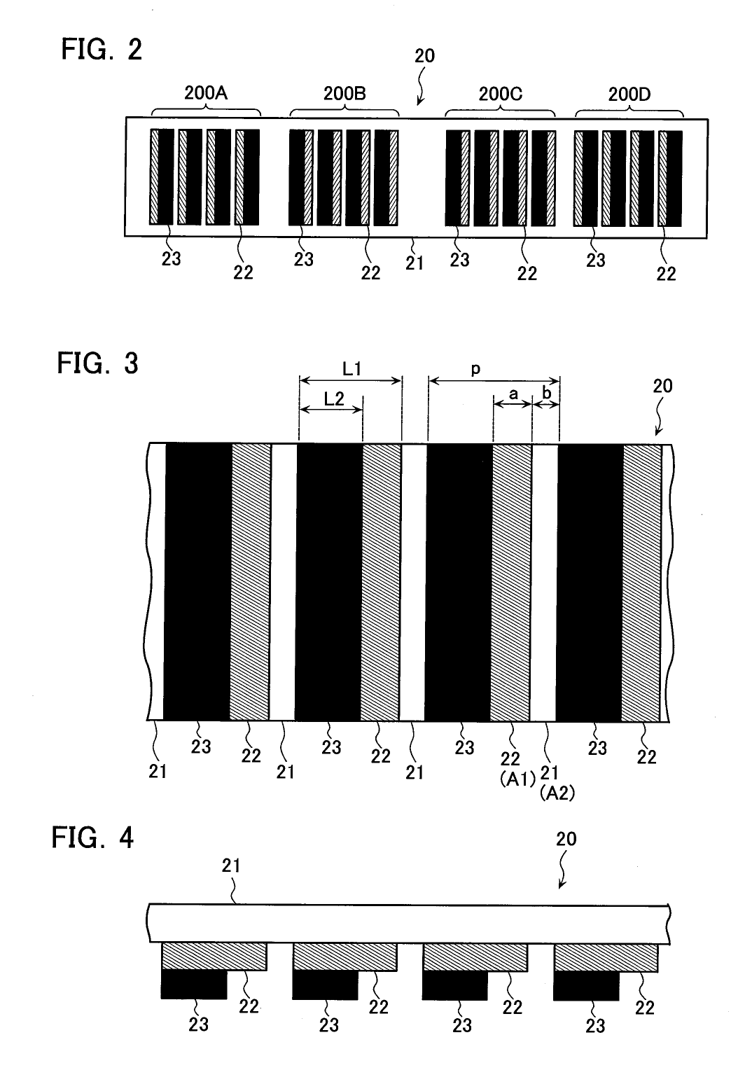

Next, a configuration of the inspection mask 20 will be explained referring to FIGS. 2 to 4. FIG. 2 is a schematic view of an upper surface of the inspection mask 20, FIG. 3 is an enlarged view of a part of FIG. 2, and FIG. 4 is a schematic side elevational view of the inspection mask 20. As shown in FIGS. 2 to 4, the inspection mask 20 has first to fourth asymmetric diffraction grating patterns 200A to 200D formed on a transparent mask substrate. The first to fourth asymmetric diffraction grating patterns 200A to 200D generate the +1-order diffracted light and the −1-order diffracted light having different diffraction efficiency.

Each of the first to fourth asymmetric diffraction grating patterns 200A to 200D is composed of a transparent substrate 21 to transmit light, an attenuated film (phase shift film) 22 formed on a surface of the transparent substrate 21 to shift a phase of light, and a shade film 23 formed on a surface of the attenuated film 22 to shade light. For example, the transparent substrate 21 is composed of quartz, the attenuated film 22 is composed of molybdenum silicide (MoSi), and the shade film 23 is composed of chromium (Cr).

The attenuated film 22 is formed to have such a thickness that a phase difference between a phase of first light passing through only the transparent substrate 21 and a phase of second light passing through the attenuated films 22 and the transparent substrate 21 has a value other than 180°×n (n is an integer equal to or larger than 0). For example, the attenuated films 22 are formed to have an amplitude transmittance of 0.495 and a thickness of 35 nm.

As shown in FIG. 2, when viewed from upper surfaces, the first and fourth asymmetric diffraction grating patterns 200A and 200D are formed such that the transparent substrate 21, the attenuated film 22, and the shade film 23 appear periodically from left to right of FIG. 2 in this order. Further, when viewed from upper surfaces, the second and third asymmetric diffraction grating patterns 200B and 200C are formed such that the transparent substrate 21, the shade film 23, and the attenuated film 22 appear periodically from left to right of FIG. 2 in this order. That is, the second asymmetric diffraction grating pattern 200B is in the relation of mirror symmetry with respect to the first asymmetric diffraction grating pattern 200A. Further, the fourth asymmetric diffraction grating pattern 200D is in the relation of mirror symmetry to the third asymmetric diffraction grating pattern 200C.

The edges of the attenuated films 22 and the edges of the shade films 23 are periodically disposed at the same predetermined pitch p (refer to FIG. 3). Further, each of the attenuated films 22 has a length L1 (L1<p) in a pitch direction, and each of the shade films 23 has a length L2 (L2<L1) in the pitch direction. In other words, the length of a region A1 composed of the transparent substrate 21 and the attenuated film 22 (hereinafter, called an attenuated region) is set to a (a=L1−L2) in the pitch direction. Further, the length of a region A2 composed of the transparent substrate 21 (hereinafter, called a transparent region) in the pitch direction is b (b=p−L1).

It is assumed here that α=a/p, β=b/p, the phase difference between the attenuated region A1 and the transparent region A2 in the inspection mask 20 is shown by φ, and the amplitude transmittance of the attenuated region A is shown by t. The inspection mask 20 is configured to satisfy the following expressions 2 and 3.

### (Expression 2)

$$t = \sqrt{\frac{{sin}^{2} ( πβ )}{{sin}^{2} ( πα )}} \qquad ( 2 )$$

### (Expression 3)

$$φ = \pm \frac{π}{2} ( α + β ) \qquad ( 3 )$$

For example, a=p/2, b=p/3, t=0.707, φ=±75° are exemplified as the conditions for satisfying the above expressions. The inspection mask 20 is configured to satisfy the above expressions 2 and 3. When the inspection mask 20 is configured as described above, it extinguishes any one of the ±1-order diffracted lights.

Next, the distribution of the light radiated to the secondary light source surface 13a of the illumination optical system 13 and the light radiated to the pupil 15a of the projection optical system 15, and the light diffracted by the inspection mask 20 will be explained referring to FIGS. 5A and 5B.

Dipole illumination is formed on the secondary light source surface 13a of the illumination optical system 13. Each of FIGS. 5A and 5B shows only one light flux of the dipole illumination (two light fluxes) formed on the secondary light source surface 13a. That is, the light, which is actually radiated to the secondary light source surface 13a, the inspection mask 20, and the pupil 15a of the projection optical system 15, is formed by overlapping the light fluxes shown in FIGS. 5A and 5B.

FIG. 5A shows illumination light obliquely incident on the secondary light source surface 13a from a first direction. The illumination light obliquely incident from the first direction is radiated to a position P2 offset from the center of the secondary light source surface 13a of the illumination optical system 13 by a predetermined distance (refer to the symbol “a” of FIG. 5A).

Subsequently, the illumination light from the illumination optical system 13 is obliquely incident on the inspection mask 20 at a predetermined angle from any orthogonal direction of the inspection mask 20. Here, the light diffracted in the inspection mask 20 is obtained by removing the +1-order diffracted light therefrom. The 0-order diffracted light travels in the direction of a predetermined angle from the orthogonal direction of the inspection mask 20, and the −1-order diffracted light travels in the direction of an angle θ from the 0-order diffracted light (refer to the symbol “b” of FIG. 5B). Then, only the 0-order diffracted light from the inspection mask 20 is radiated to a predetermined position P2 (0) of the pupil 15a of the projection optical system 15 (refer to a symbol “c” of FIG. 5A). That is, since only the 0-order diffracted light is radiated to the pupil 15a of the projection optical system 15, no interference fringe is formed on the wafer W.

FIG. 5B shows illumination light obliquely incident on the secondary light source surface 13a from a second direction. The illumination light obliquely incident from the second direction is radiated to a position P3 offset from the center of the secondary light source surface 13a of the illumination optical system 13 by a predetermined distance (refer to the symbol “a” of FIG. 5B). Note that the illumination light obliquely incident from the second direction is radiated to symmetrical positions from the center thereof as compared with the case of FIG. 5A. Subsequently, the illumination light from the illumination optical system 13 is obliquely incident on the inspection mask 20 at a predetermined angle from the orthogonal direction of the inspection mask 20. Here, the light diffracted in the inspection mask 20 is obtained by removing the +1-order diffracted light therefrom. The 0-order diffracted light travels in the direction of a predetermined angle from the orthogonal direction of the inspection mask 20, and the −1-order diffracted light travels in the direction of an angle θ from 0-order diffracted light (refer to the symbol “b” of FIG. 5B). Then, the 0-order diffracted light and the −1-order diffracted light from the inspection mask 20 are radiated to predetermined positions P3 (0), P3 (−1) of the pupil 15a of the projection optical system 15 (refer to a symbol “c” of FIG. 5B). That is, since the 0-order diffracted light and the −1-order diffracted light are radiated to the pupil 15a of the projection optical system 15, an interference fringe is formed on the wafer W.

As described above, the illumination light radiated to the secondary light source surface 13a from the first direction forms no interference fringe on the wafer W. In contrast, the illumination light radiated to the secondary light source surface 13a from the second direction forms an interference fringe on the wafer W. Accordingly, an interference fringe is formed on the wafer W by the light obtained by combining the illumination light from the first direction and the illumination light from the second direction.

Here, as shown in a symbol “a” of FIG. 5C, the illumination poles Q2 and Q3 on the secondary light source surface 13a are not formed in a circular shape but formed in a shape other than the circular shape such as a fan shape according to the configuration of the exposure apparatus 10. In this case, virtual circles Qa2 and Qa3 including the illumination poles Q2 and Q3 are assumed as shown in a symbol “b” of FIG. 5C. Then, the radius σᵣ of the illumination pole in the expression 1 is defined using the circles Qa2 and Qa3.

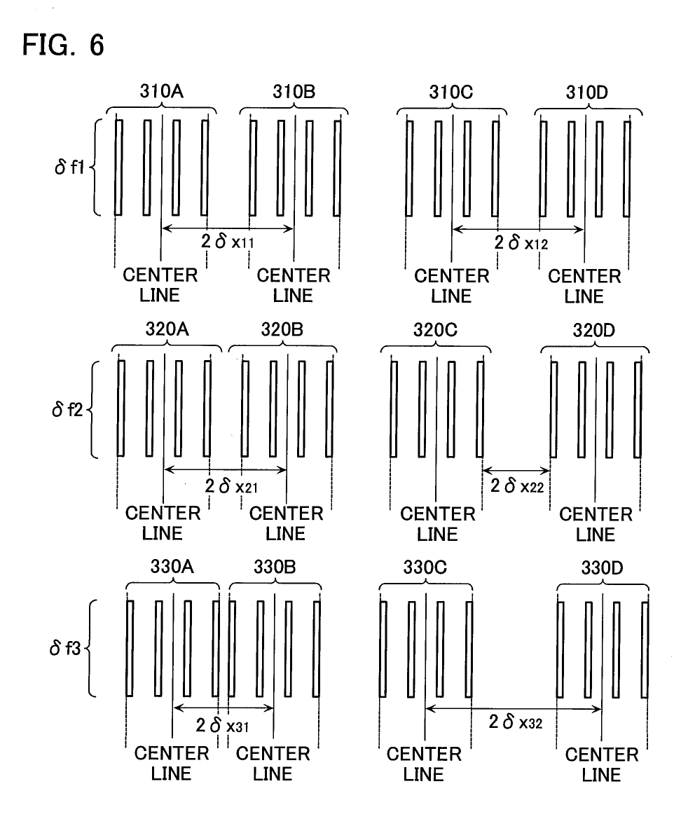

Subsequently, a focus pattern projected on the wafer W through the inspection mask 20 will be explained referring to FIG. 6. FIG. 6 is a view explaining an outline of the focus pattern projected on the wafer W. In FIG. 6, the focus pattern is measured in the state that first to third different focus offset amounts δf1 to δf3 are given. Note that the focus offset amount means an amount offset from a focused position on the wafer W. In FIG. 6, it is assumed that first focus offset amount δf1<second focus offset amount δf2<third focus offset amount δf3. In the first focus offset amount δf1, the first to fourth focus patterns 310A to 310D are formed from left to right in FIG. 6. The first to fourth focus patterns 310A to 310D are generated by the diffracted lights of the first to fourth asymmetric diffraction grating patterns 200A to 200D. Likewise, in the second and third focus offset amounts δf2 and δf3, the first to fourth focus patterns 320A to 320D and the first to fourth focus patterns 330A to 330D are also generated, respectively, on the wafer W by the diffracted lights of the first to fourth asymmetric diffraction grating patterns 200A to 200D.

Here, it is assumed that the distance between the center line of the first focus pattern 310A and the center line of the second focus pattern 310B in the first focus offset amount δf1 is shown by a first relative distance 2δx11. Further, it is assumed that the distance between the center line of the first focus pattern 320A and the center line of the second focus pattern 320B in the second focus offset amount δf2 is shown by a second relative distance 2δx21, and the distance between the center line of the first focus pattern 330A and the center line of the second focus pattern 330B in the third focus offset amount δf3 is shown by a third relative distance 2δx31. Referring to FIG. 6, the first to third relative distances 2δx11 to 2δx31 change according to the first to third focus distances δf1 to δf3.

Likewise, first to third relative distance 2δx12 to 2δx32, which are the distances between the third focus patterns 310C, 320C, and 330C and the fourth focus patterns 310D, 320D, and 330D change according to the first to third focus offset amounts δf1 to δf3.

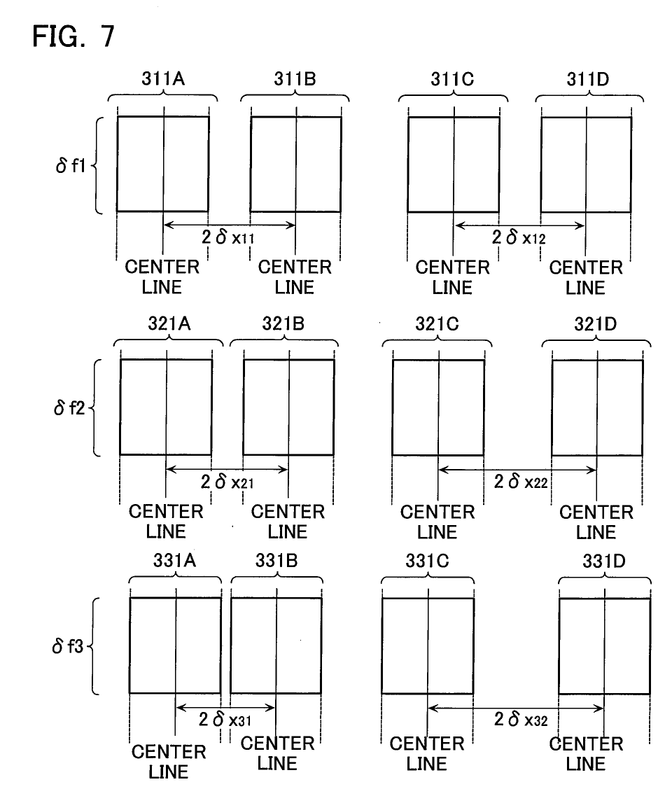

FIG. 7 shows a case in which focus patterns 311A to 331D are observed on the wafer W in a block shape in place of a stripe shape. These focus patterns 311A to 311D are obtained by picking up with a measurement apparatus, which has an insufficient resolution to observe a fine structure of focus patterns. Even in this case, the first to third relative distances 2δx11 to 2δx31, and 2δx12 to 2δx32 in the first to third focus offset amounts δf1 to δf3 can be observed.

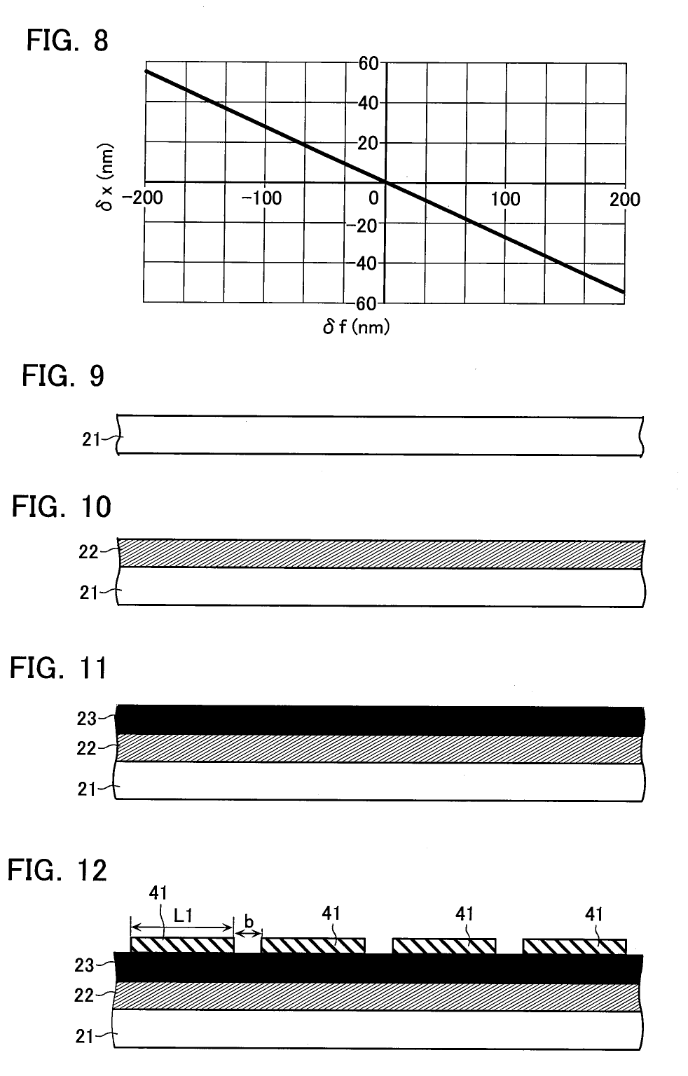

FIG. 8 is a view showing a result calculated by simulating a relative distance δx to a focus offset amount δf. As shown in FIG. 8, the relative distance δx is in proportion to the focus offset amount δf. That is, the focus offset amount δf can be determined by measuring the relative distance δx.

Next, manufacturing steps of the inspection mask 20 of the first embodiment will be explained referring to FIGS. 9 to 15. FIGS. 9 to 15 are views showing the manufacturing steps of the inspection mask 20.

First, as shown in FIG. 9, the transparent substrate 21 composed of quartz is prepared. Subsequently, as shown in FIG. 10, the attenuated film 22 composed of MoSi (molybdenum silicide) is deposited on the transparent substrate 21. Next, as shown in FIG. 11, the shade film 23 composed of Cr (chromium) is deposited on the attenuated film 22. The attenuated film 22 is deposited with the amplitude transmittance of 0.495 and the thickness of 35 nm.

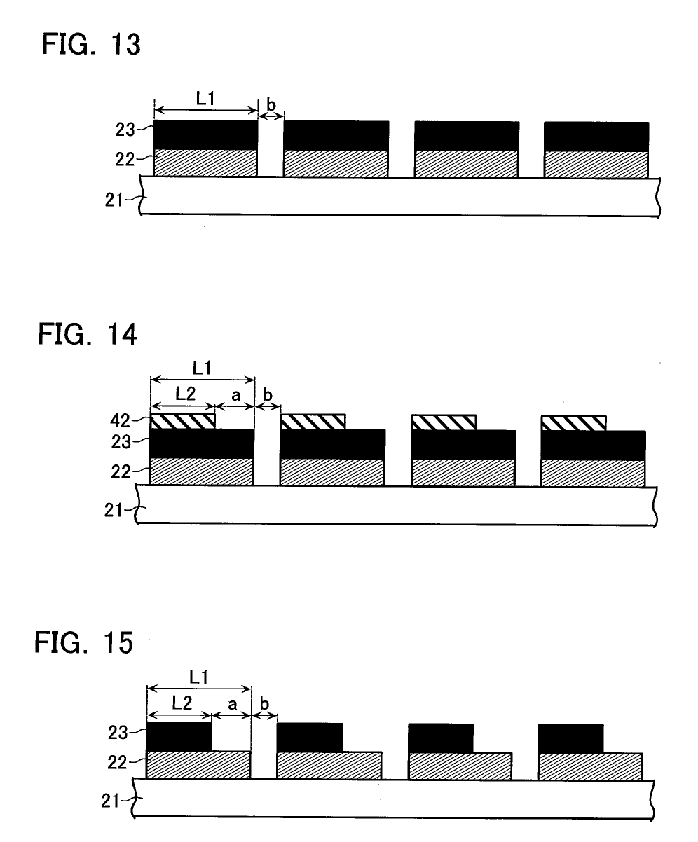

Subsequently, as shown in FIG. 12, resists 41 are formed on the shade film 23 with a length L1 in a pitch direction at intervals of a distance b in respective pitch directions. Next, as shown in FIG. 13, the shade film 23 and the attenuated film 22 are removed by etching, and the resists 41 are stripped.

Subsequently, as shown in FIG. 14, resists 42 are formed on the resists 41 with a length L2 in the pitch direction at intervals of a distance a+b in the respective pitch directions. Then, as shown in FIG. 15, the shade film 23 is removed by etching, and the resists 42 are stripped. The inspection mask 20 shown in FIGS. 2 to 4 is manufactured through the above steps.

As described above, in the manufacturing steps of the inspection mask 20 according to the first embodiment, the attenuated film 22 is previously formed to a thickness for creating light having a predetermined phase difference. Accordingly, since it is not necessary to engrave the attenuated film 22, the manufacturing steps can be simplified and the inspection mask 20 can be provided at a low cost.

Further, the etching can be finished at a more appropriate position by more increasing the etching speed of the attenuated film 22 than that of the transparent substrate 21 in the first etching step (refer to FIG. 13) as well as by more increasing the etching speed of the shade film 23 than that of the attenuated film in the second etching step (refer to FIG. 15).

Further, since the shapes of the attenuated film 22 and the shade film 23 of the inspection mask 20 are determined according to the expressions 2 and 3, any one of the +1-order diffracted lights can be extinguished even in the inspection mask 20 without engraving.

### Second Embodiment

Next, an exposure apparatus according to a second embodiment will be explained. The exposure apparatus according to the second embodiment is approximately the same as that of the first embodiment (FIG. 1). The exposure apparatus according to the second embodiment has an inspection mask 20a different from that of the first embodiment. Further, in the exposure apparatus according to the second embodiment, an operation of a controller 18 is different from that of the first embodiment. Note that in the second embodiment, the same arrangements as those of the first embodiment are denoted by the same reference numerals, and the explanation thereof is omitted.

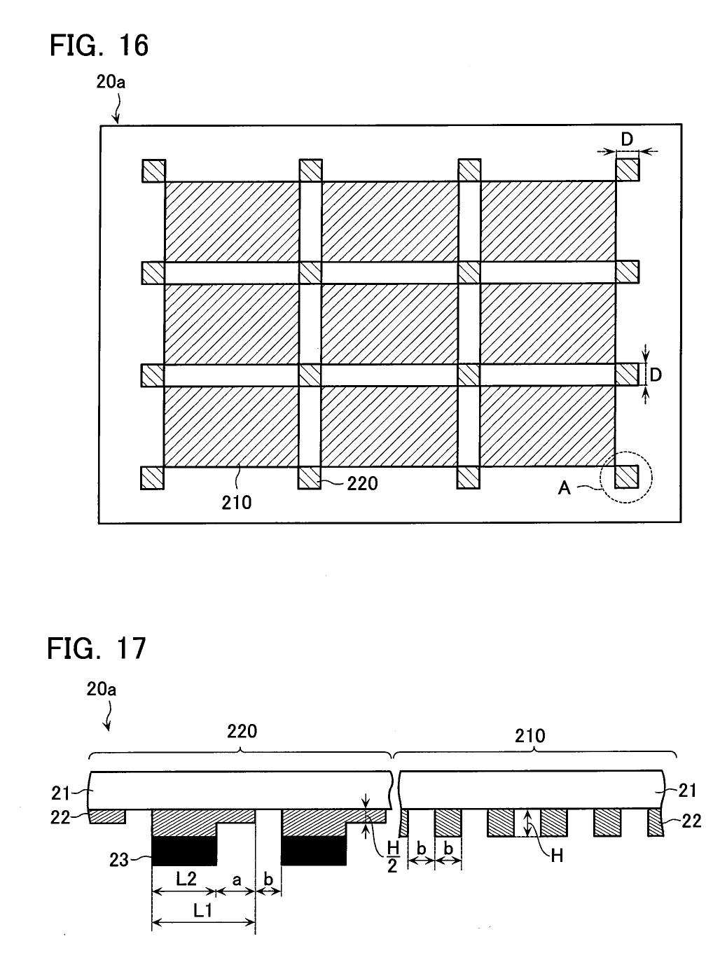

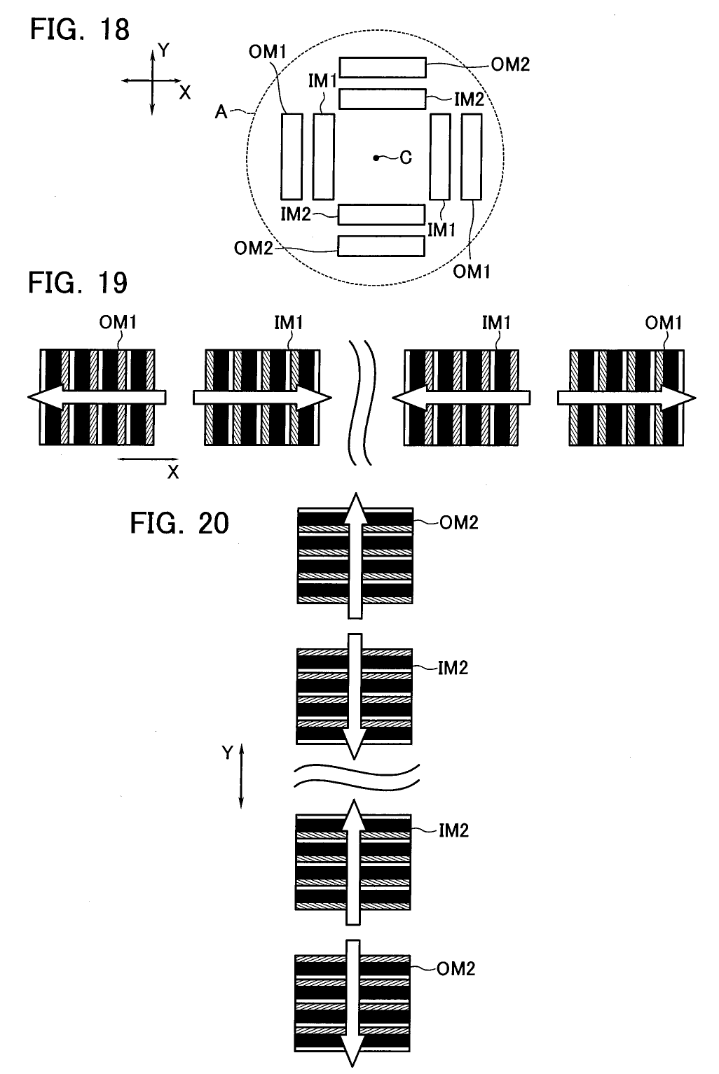

First, a configuration of the inspection mask 20a will be explained referring to FIGS. 16 to 20. FIG. 16 is a schematic upper surface view of the inspection mask 20a, FIG. 17 is a sectional view of the inspection mask 20a, and FIG. 18 is an enlarged view of a part A of FIG. 16.

As shown in FIG. 16, the inspection mask 20a has a plurality of rectangular device pattern regions 210 and a plurality of rectangular focus adjustment pattern regions 220.

The plurality of device pattern regions 210 are used to expose device patterns on the wafer W. The plurality of device pattern regions 210 are formed at predetermined intervals D in up, down, right and left directions. Dicing regions, which act as wafer cutting lines in the manufacturing steps of a semiconductor product, are formed between the plurality of device pattern regions 210. As shown in FIG. 17, the device pattern regions 210 are composed of a transparent substrate 21 and attenuated films 22 formed thereon. In the device pattern regions 210, the attenuated films 22 are formed at a predetermined pitch b. Further, in the device pattern regions 210, the attenuated films 22 have a first thickness H so that the light passing through only the transparent substrate 21 and the light passing through the transparent substrate 21 and the attenuated films 22 have a phase difference of 180° (refer to FIG. 17). The attenuated films 22 are formed such that the first thickness H is set to, for example, 70 nm and an amplitude transmittance is set to 0.245 (intensity transmittance is set to 6%). Note that it is only necessary that the first thickness H be set to such a thickness that the phase difference between the phase of the first light passing through only the transparent substrate 21 and the phase of the second light passing through the transparent substrate 21 and the attenuated films 22 is set to 180°×n (n is an integer equal to or more than 0).

The plurality of focus adjustment pattern regions 220 are used to adjust a focus in an exposure apparatus as in the first embodiment. The plurality of focus adjustment pattern regions 220 are disposed in the dicing regions adjacent to four corners of the respective device pattern regions 210. The focus adjustment pattern region 220 is composed of the transparent substrate 21, the attenuated films 22, and shade films 23. However, in the focus adjustment pattern region 220, the attenuated films 22 have the same thickness as the first thickness H as well as have surfaces on which the shade films 23 are formed. Further, the attenuated films 22 have a surface having a second thickness H/2 so that the light passing through only the transparent substrate 21 and the light passing through the transparent substrate 21 and the attenuated films 22 have a phase difference of 90° (refer to FIG. 17). For example, the attenuated films 22 are formed such that they have the second thickness of 35 nm and the amplitude transmittance of 0.495. Note that it is only necessary that the second thickness H/2 be set to such a thickness that the phase difference between the phase of third light passing through only the transparent substrate 21 and the phase of fourth light passing through the transparent substrate 21 and the attenuated films 22 is set to a value other than 180°×n (n is an integer equal to or more than 0). That is, the focus adjustment pattern region 220 is configured such that the phase difference φ and the amplitude transmittance t satisfy the expressions 2 and 3 shown in the first embodiment as in the first embodiment. A condition for satisfying the expressions 2 and 3 is, for example, a=p/2, b=p/3, t=0.707, φ=±750.

As shown in FIG. 18, the focus adjustment pattern region 220 has a pair of first inner marks IM1 disposed in confrontation with each other in an X-axis direction about a point C and a pair of second inner marks IM2 disposed in confrontation with each other in a Y-axis direction about the point C (a direction orthogonal to the X-axis direction). Further, the focus adjustment pattern region 220 has a pair of first outer marks OM1 disposed away from the point C in the X-axis direction externally of the pair of first inner marks IM1. Further, the focus adjustment pattern region 220 has a pair of second outer marks OM2 disposed away from the point C in the Y-axis direction externally of the pair of second inner marks IM2. Note that the first and second inner marks IM1, IM2 and the first and second outer marks OM1, OM2 correspond to the asymmetric diffraction grating patterns of the first embodiment.

Next, referring to FIGS. 19 and 20, configurations of the first and second inner marks IM1, IM2 and the first and second outer marks OM1, OM2 will be explained. As shown in FIGS. 19 and 20, the first and second inner marks IM1, IM2 and the first and second outer marks OM1, OM2 are configured such that the transparent substrates 21, the attenuated films 22, and the shade films 23 are repeatedly formed on the surfaces thereof. Note that void arrows in FIGS. 19 and 20 are shown such that the arrow heads thereof face the direction in which the transparent substrate 21, the attenuateds film 22, the shade films 23, the transparent substrate 21, . . . , are repeatedly formed in this order.

As shown in FIG. 19, the pair of first inner marks IM1 are formed such that the arrow heads of the void arrows face the point C along the X-axis direction. Further, the pair of first outer marks OM1 are formed such that the arrow heads of the void arrows face the direction away from the point C along the X-axis direction.

As shown in FIG. 20, the pair of second inner marks IM2 are formed such that the arrow heads of the void arrows face the point C along the Y-axis direction. Further, the pair of second outer marks OM2 are formed such that the arrow heads of the void arrows face the direction away from the point C along the Y-axis direction.

The difference between the focus offset amounts in the X-axis direction and the Y-axis direction, i.e., astigmatism can be measured by the first inner mark IM1, the first outer mark OM1, and the second inner mark IM2, and the second outer mark OM2. When, for example, the inspection mask 20a is used, a relative distance changes over 27 nm with respect to the change of the focus offset amount of 100 nm.

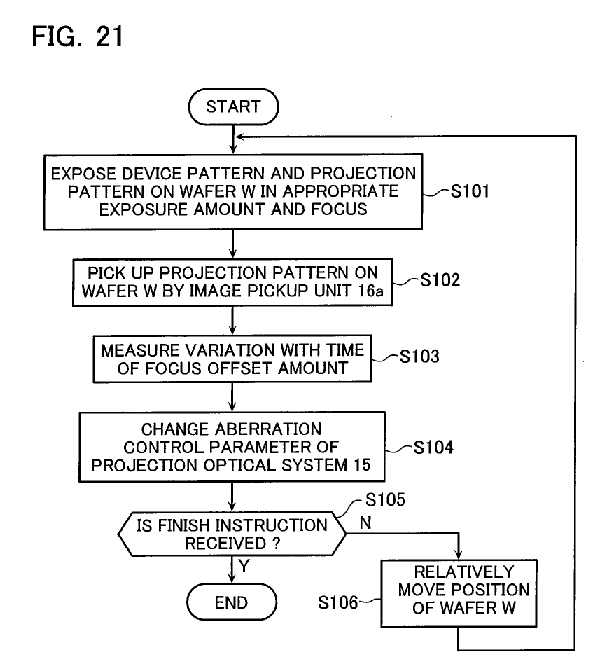

Next, an exposure operation of the exposure apparatus according to the second embodiment will be explained referring to FIG. 21. FIG. 21 is a flowchart explaining the exposure operation of the exposure apparatus. Note that the operation shown in FIG. 21 is controlled by a controller 18 of the exposure apparatus.

As shown in FIG. 21, first, the controller 18 copies a device pattern and a focus pattern on the wafer W in an exposure amount and a focus amount which are suitable for the exposure of the device patterns (step S101). Subsequently, the controller 18 causes an image pickup unit 16a to pick up the focus patterns on the wafer W (step S102). The imaged pattern is a latent image pattern generated after exposure, or a resist pattern generated by wafer development.

Next, the controller 18 measures the variation with time of the focus offset amount based on the picked up focus patterns (step S103). Subsequently, the controller 18 changes aberration control parameter of the projection optical system 15 based on the variation with time of the measured focus offset amount (step S104).

Next, the controller 18 determines whether or not it receives an instruction for finishing the exposure operation (step S105). When the controller 18 determines that it does not receive the finish instruction (step S105, N), it relatively moves the position of the wafer W with respect to the position to which light is illuminated from an exposure light source 11 (step S106) and performs the operations from steps S101 to S104 again. In contrast, when the controller 18 determines that it receives the finish instruction (step S105, Y), it finishes the exposure operation. The exposure operation of the exposure apparatus is finished as described above.

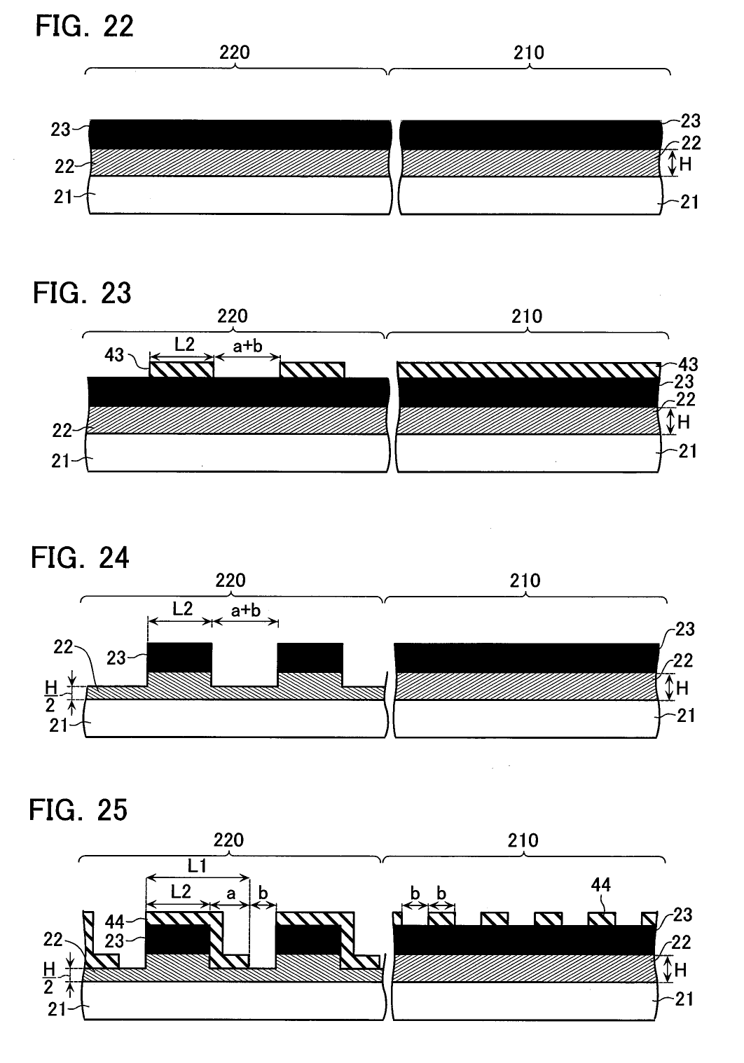

Next, manufacturing steps of the inspection mask 20a according to the second embodiment will be explained referring to FIGS. 22 to 28. FIGS. 22 to 28 are views showing the manufacturing steps of the inspection mask 20a according to the second embodiment.

As shown in FIG. 22, first, the attenuated film 22 is formed on the transparent substrate 21 and further the shade film 23 is formed thereon as in the manufacturing steps of the first embodiment (refer to FIGS. 9 to 11). Note that in FIG. 22, the attenuated film 22 is formed to such a thickness H that a diffracted light having a phase difference of 180° is diffracted.

Subsequently, as shown in FIG. 23, a resist 43 is formed to cover the entire region of the shade film 23 in the device pattern region 210. Further, resists 43 having a width L2 are formed on the shade film 23 at intervals of a+b in the focus adjustment pattern region 220.

Next, as shown in FIG. 24, the region in which the resists 43 are not formed is etched. The shade film 23 is removed in the region of the focus adjustment pattern region 220 subjected to the etching, and the region is engraved to a thickness H/2 by which the attenuated film 22 creates a diffracted light having a phase difference of 90°. Note that the resists 43 are removed after the etching.

Subsequently, as shown in FIG. 25, resists 44 having a width b are formed on the shade film 23 at intervals b in the device pattern region 210. Further, resists 44 are formed to cover parts of the shade film 23 and the attenuated film 22 thereon in the focus adjustment pattern region 220. In other words, the resists 44 having a width L1 (L2+a) are formed at intervals b in the focus adjustment pattern region 220.

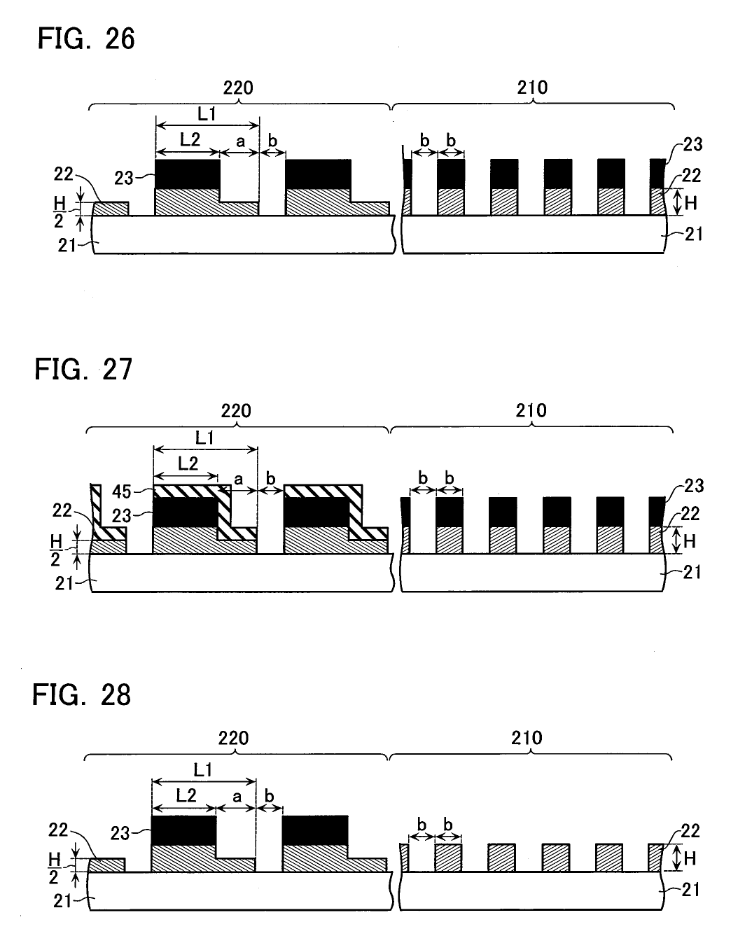

Next, as shown in FIG. 26, the region in which the resists 44 are not formed is etched. With this operation, regions having a width b, from which the front surface of the transparent substrate 21 is exposed, are formed at intervals b in the device pattern region 210. Further, regions having the width b, from which the front surface of the transparent substrate 21 is exposed, are formed at intervals L1 in the device pattern region 220. Note that the resists 44 are removed after the etching.

Subsequently, as shown in FIG. 27, resists 45 are formed to cover the shade films 23 and the attenuated films 22 in the device pattern region 220. The resists 45 having a width L1 are formed at intervals b.

Next, as shown in FIG. 28, the region in which no resist 45 is formed is etched. With this operation, the shade films 23 in the device pattern region 210 are entirely removed. Then, the resists 45 are removed after the etching, and the inspection mask 20a is formed as in FIG. 20.

Further, according to the exposure operation of the exposure apparatus of the second embodiment, the device patterns can be formed as well as the focus offset amount of each region, which is illuminated by the exposure performed once, can be measured. That is, formation of the device patterns and measurement of the focus offset amount can be performed by the exposure performed once without performing the exposure individually.

Note that there is a phenomenon, in which optical elements in the projection optical system 15 changes shape when the projection optical system 15 is heated by the light radiated thereto and aberration (thermal aberration) occurs as a factor for causing a phenomenon in which the focus offset amount is varied by exposure. According to the exposure operation of the exposure apparatus of the second embodiment, the influence of thermal aberration can be eliminated by adjusting aberration of the projection optical system 15 based on the variation with time of the focus patterns. That is, according to the exposure operation of the exposure apparatus of the second embodiment, an exposure of a pinpoint accuracy can be performed by eliminating the influence of thermal aberration.

### Third Embodiment

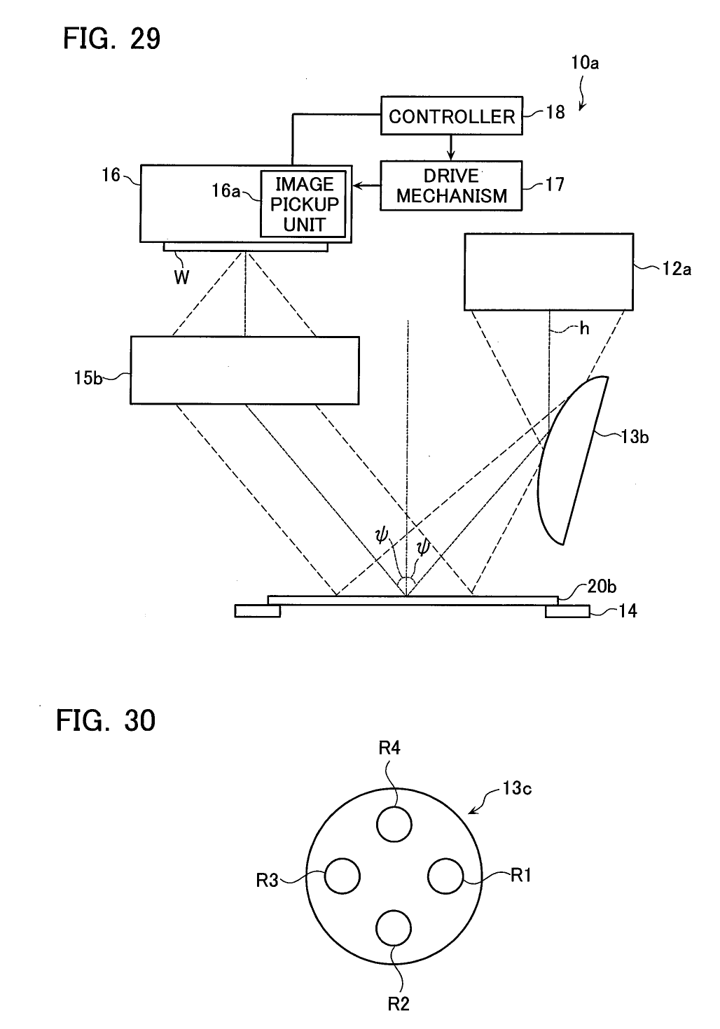

Next, an exposure apparatus 10a according to a third embodiment of the present invention will be explained referring to FIG. 29. FIG. 29 shows a schematic view of the exposure apparatus 10a according to the third embodiment of the present invention. Note that, in the third embodiment, the same configurations as those of the first embodiment are denoted by the same reference numerals, and the explanation thereof is omitted.

As shown in FIG. 29, the exposure apparatus 10a according to the third embodiment is configured as a reflection type in contrast to the exposure apparatus 10 according to the first embodiment configured as the transmission type. The exposure apparatus 10a according to the third embodiment has a light source optical system 12a, an inspection mask 20b, and a projection optical system 15b which are different from those of the first embodiment. The exposure apparatus 10a according to the third embodiment has a mirror 13b in place of the illumination optical system 13 of the first embodiment. Further, the exposure apparatus 10a of the third embodiment is different from that of the first embodiment in that the other arrangements (a photo mask stage 14, the projection optical system 15b, a wafer stage 16, and the like) are disposed in correspondence to the light source optical system 12a and the inspection mask 20b.

The light source optical system 12a radiates EUV light (light having a wavelength of 13.5 nm). The inspection mask 20b is configured as the reflection type so as to reflect the illumination light and the inspection light from the light source optical system 12a. The mirror 13b is disposed such that the light radiated from the light source optical system 12a is incident on the front surface of the inspection mask 20b at a predetermined angle φ. The projection optical system 15b is arranged to guide the light reflected from the inspection mask 20b to a wafer W.

The focus patterns which has the configuration showing in FIG. 3 and FIG. 4 are formed on the surface of the inspection mask 20b. In the inspection mask 20b, the regions 21 is a high-reflection area (reflecting substrate), the region 22 is a medium-reflection area (phase shifter films), and the region 23 is an absorption area (absorption films). The region 22 has reflectivity to irradiated light which is lower than one of the region 21. The area 22 is formed to have such a thickness that a phase difference between a phase of first light reflecting only the area 21 and a phase of second light reflecting only the area 22 is set to a value other than 180°×n (n is an integer equal to or larger than 0). For example, the area 21, 22 comprise multilayer film which alternately accumulated molybdenum and silicon. For example, the area 32 comprises tantalum nitride.

The exposure apparatus 10a according to the third embodiment having the above configuration has the same advantage as that of the first embodiment.

Although the embodiments of the present invention have been explained above, the invention is not limited to the embodiments, and various modifications, additions, replacements, and the like can be made within a scope which does not depart from the gist of the invention. For example, although the illumination optical system 13 and the projection optical system 15 are configured as refraction optical systems in the above embodiments, they may be configured as reflection optical systems, or mixed refraction/reflection optical systems. Further, the configuration of the exposure apparatus 10 according to the first embodiment is not limited to the dipole illumination and can be also made adaptive to quadrupole illumination. In the quadrupole illumination, four illumination poles R1 to R4 are formed on the secondary light source surface 13c as shown in FIG. 30. For example, using the quadrupole illumination in FIG. 30, only 0-order diffracted light in the newly added illumination poles R2, R4 pass through a pupil 15a of the projection optical system 15, so new images aren't generated on the wafer W. Accordingly, focus patterns generated by the illumination poles R1, R3 does not change shape. Namely, it can inspect as first embodiment by the quadrupole illumination.

Further, in the above embodiments, the following configurations (1), (2) are also shown.

(1) An exposure apparatus inspection mask, which is an exposure apparatus inspection mask 20a in which a device pattern region 210 used to expose a device pattern and a focus adjustment pattern region (asymmetric diffraction grating region) 220 for generating +1-order diffracted light and −1-order diffracted light having a different diffraction efficiency are disposed, wherein the device pattern region 210 has a transparent substrate 21 and a plurality of attenuated films (first phase shifter films) 22 formed on the transparent substrate 21. The focus adjustment pattern region 220 has a transparent substrate 21, attenuated films 22 (second phase shifter films) selectively and periodically disposed on the substrate at a predetermined pitch and a plurality of the shade films 23 formed on the attenuated films 22. The attenuated films (first phase shifter films) 22 of the device pattern region 210 has a first thickness. The attenuated films (second phase shifter films) 22 of the focus adjustment pattern region 220 has a second thickness. The first thickness is set to such a thickness that a phase difference between a phase of first light passing through only the transparent substrate 21 in the device pattern region 210 and a phase of second light passing through the transparent substrate 21 and the attenuated films 22 in the device pattern region 210 is set to 180°×n (n is an integer equal to or more than 0). The second thickness is set to such a thickness that the phase difference between the phase of third light passing through only the transparent substrate 21 in the focus adjustment pattern region 220 and the phase of fourth light passing through the transparent substrate 21 and the attenuated films 22 in the focus adjustment pattern region 220 is set to a value other than 180°×n (n is an integer equal to or more than 0).

(2) An exposure apparatus having a mask stage 14 on which an exposure apparatus inspection mask 20 in which asymmetric diffraction grating regions 200A to 200D for generating +1-order diffracted light and −1-order diffracted light having a different diffraction efficiency are disposed is placed, a light source optical system 12 for radiating obliquely incident light to the exposure apparatus inspection mask 20 from a direction offset by a first angle from a vertical direction, and a projection optical system 15 for projecting the obliquely incident light to a wafer (substrate) W, wherein the exposure apparatus inspection mask 20 has a transparent substrate 21, semi-transparent attenuated films 22 selectively and periodically disposed on the transparent substrate 21 at a predetermined pitch, and shade films 23 selectively and periodically disposed on the attenuated films 22 at a predetermined pitch. The attenuated films 22 are formed to have such a thickness that a phase difference between a phase of first light passing through only the transparent substrate 21 and a phase of second light passing through the attenuated films 22 and the transparent substrate 21 has a value other than 180°×n (n is an integer equal to or larger than 0), and the following expression is satisfied when an exposure wavelength is shown by λ, the numerical aperture of the projection optical system 15 is shown by NA, a pitch is set to p, the distance from the center of a pupil 15a of the projection optical system 15 to the center of an illumination pole is shown by σ_{c}, and the radius of the illumination pole is shown by σᵣ.

### (Expression 4)

$$\frac{λ}{2 {σ}_{c} \cdot NA} < p < \frac{2 λ}{NA ( {σ}_{c} + {σ}_{r} + 1 )} \qquad ( 4 )$$

Further, in the above embodiments, the following methods of manufacturing are also shown.

(Methods of Manufacturing 1)

A method of manufacturing an exposure apparatus inspection mask having asymmetric diffraction grating regions disposed on a transparent substrate for generating +1-order diffracted light and −1-order diffracted light having a different diffraction efficiency, the method comprising:

forming semi-transparent phase shifter films on the transparent substrate;

forming shade films on the phase shifter films;

forming first regions from which the phase shifter films and the shade films are selectively and periodically removed at a predetermined pitch; and

forming second regions from which the shade films are selectively and periodically removed at a predetermined pitch and in which the phase shifter films remain,

wherein the phase shifter films are formed to have such a thickness that a phase difference between the phase of first light passing through the first regions and a phase of second light passing through a second regions is set to a value other than 180°×n (n is an integer equal to or larger than 0).

(Methods of Manufacturing 2)

The method of manufacturing an exposure apparatus inspection mask according to (methods of manufacturing 1), wherein when the length of the predetermined pitch is shown by p, the length in the pitch direction of the regions in which the phase shifter films are exposed to a surface is shown by a, the length in the pitch direction of the regions in which the transparent substrate is exposed to the surface is shown by b, the phase difference is shown by φ, the amplitude transmittance of the phase shifter films is shown by t, α=a/p, and β=b/p, the following expressions are satisfied:

$$t = \sqrt{\frac{{sin}^{2} ( πβ )}{{sin}^{2} ( πα )}}$$

$$φ = \pm \frac{π}{2} ( α + β )$$

(Methods of Manufacturing 3)

The method of manufacturing an exposure apparatus inspection mask according to (methods of manufacturing 1), wherein four sets of the asymmetric diffraction grating regions are disposed so as to be arranged in a predetermined direction, and

the asymmetric diffraction grating regions are formed so that the first asymmetric diffraction grating region is in the relation of mirror symmetry to the second asymmetric diffraction grating region, and the third asymmetric diffraction grating region is in the relation of mirror symmetry to the fourth asymmetric diffraction grating region.

(Methods of Manufacturing 4)

The method of manufacturing an exposure apparatus inspection mask according to (methods of manufacturing 1), wherein

the transparent substrate comprises quartz,

the phase shifter films comprise molybdenum silicide, and

the shade films comprise chromium.

(Methods of Manufacturing 5)

A method of manufacturing an exposure apparatus inspection mask having device pattern regions used to expose a device pattern and asymmetric diffraction grating regions for generating +1-order diffracted light and −1-order diffracted light each disposed on a transparent substrate, the method comprising:

forming semi-transparent phase shifter films having a first thickness on the transparent substrate;

forming shade films on the phase shifter films;

selectively and periodically removing the shade films at a predetermined pitch in the asymmetric diffraction grating regions;

making the phase shifter films to a second thickness at the positions where the shade films of the asymmetric diffraction grating regions are removed;

selectively and periodically removing the phase shifter films and the shade films together at a predetermined pitch in the device pattern regions and the asymmetric diffraction grating regions; and

removing the shade films in the asymmetric diffraction grating regions,

wherein the first thickness is such that a phase difference between a phase of first light passing through only the transparent substrate in the device pattern regions and a phase of second light passing through the transparent substrate and the phase shifter films in the device pattern regions is set to 180°×n (n is an integer equal to or larger than 0), and

the second thickness is such that a phase difference between a phase of third light passing through only the transparent substrate in the asymmetric diffraction grating regions and a phase of fourth light passing through the transparent substrate and the phase shifter films in the asymmetric diffraction grating regions is set to a value other than 18°×n (n is an integer equal to or larger than 0).

(Methods of Manufacturing 6)

The method of manufacturing an exposure apparatus inspection mask according to (methods of manufacturing 5), wherein when the length of the predetermined pitch is shown by p, the length in the pitch direction of the regions in which the phase shifter films in the asymmetric diffraction grating regions are exposed to a surface is shown by a, the length in the pitch direction of the regions in which the transparent substrate in the asymmetric diffraction grating regions is exposed to the surface is shown by b, the phase difference is shown by φ, the amplitude transmittance of the phase shifter films is shown by t, α=a/p, and β=b/p, the following expressions are satisfied:

$$t = \sqrt{\frac{{sin}^{2} ( πβ )}{{sin}^{2} ( πα )}}$$

$$φ = \pm \frac{π}{2} ( α + β )$$

(Methods of Manufacturing 7)

The method of manufacturing an exposure apparatus inspection mask according to (methods of manufacturing 5), wherein four sets of the asymmetric diffraction grating regions are disposed so as to be arranged in a first direction, and

the asymmetric diffraction grating regions are formed so that the first asymmetric diffraction grating region in the first direction is in the relation of mirror symmetry to the second asymmetric diffraction grating region in the first direction, and the third asymmetric diffraction grating region in the first direction is in the relation of mirror symmetry to the fourth asymmetric diffraction grating region in the first direction.

(Methods of Manufacturing 8)

The method of manufacturing an exposure apparatus inspection mask according to (methods of manufacturing 7), wherein

four sets of the asymmetric diffraction grating regions are disposed so as to be arranged in a second direction orthogonal to a first direction, and the asymmetric diffraction grating regions are formed so that the first asymmetric diffraction grating region in the second direction is in the relation of mirror symmetry to the second asymmetric diffraction grating region in the second direction and the third asymmetric diffraction grating region in the second direction is in the relation of mirror symmetry to the fourth asymmetric diffraction grating region in the second direction.

(Methods of Manufacturing 9)

The method of manufacturing an exposure apparatus inspection mask according to (methods of manufacturing 5), wherein

the transparent substrate comprises quartz,

the phase shifter films comprise molybdenum silicide, and

the shade films comprise chromium.

(Methods of Manufacturing 10)

The method of manufacturing an exposure apparatus inspection mask according to (methods of manufacturing 5), wherein the device pattern regions are disposed in a first direction and a second direction orthogonal to the first direction at predetermined intervals, and

the asymmetric diffraction grating regions are formed outside the device pattern regions.

What is claimed is:

1. An exposure apparatus inspection mask having asymmetric diffraction grating regions for generating +1-order diffracted light and −1-order diffracted light having a different diffraction efficiency,
each of the asymmetric diffraction grating regions comprising:
a transparent substrate;
semi-transparent phase shifter films selectively and periodically disposed on the transparent substrate at a predetermined pitch; and
shade films selectively and periodically disposed on the phase shifter films at a predetermined pitch,
the phase shifter films being formed to have such a thickness that a phase difference between a phase of first light passing through only the transparent substrate and a phase of second light passing through the phase shifter films and the transparent substrate is set to a value other than 180°×n (n is an integer equal to or larger than 0).

2. The exposure apparatus inspection mask according to claim 1, wherein when the length of the predetermined pitch is shown by p, the length in the pitch direction of the regions in which the phase shifter films are exposed to a surface is shown by a, the length in the pitch direction of the regions in which the transparent substrate is exposed to the surface is shown by b, the phase difference is shown by φ, the amplitude transmittance of the phase shifter films is shown by t, α=a/p, and β=b/p, the following expressions are satisfied.
$$t = \sqrt{\frac{{sin}^{2} ( πβ )}{{sin}^{2} ( πα )}}$$
$$φ = \pm \frac{π}{2} ( α + β )$$

3. The exposure apparatus inspection mask according to claim 1, wherein
four sets of the asymmetric diffraction grating regions are disposed so that they are arranged in a predetermined direction,
the first asymmetric diffraction grating region is in the relation of mirror symmetry to the second asymmetric diffraction grating region, and
the third asymmetric diffraction grating region is in the relation of mirror symmetry to the fourth asymmetric diffraction grating region.

4. The exposure apparatus inspection mask according to claim 1, wherein
the transparent substrate comprises quartz,
the phase shifters comprise molybdenum silicide, and
the shade films comprise chromium.

5. A method of inspecting an exposure apparatus using an exposure apparatus inspection mask having device pattern regions used to expose a device pattern and asymmetric diffraction grating regions for generating +1-order diffracted light and −1-order diffracted light having a different diffraction efficiency, each region being disposed on a transparent substrate, the method comprising:
exposing the device pattern regions and the asymmetric diffraction grating regions and projecting them onto a substrate;
imaging focus patterns obtained by exposing the asymmetric diffraction grating regions projected onto the substrate;
obtaining information as to the state of a projection optical system for projecting light to the substrate based on the imaged focus pattern; and
correcting the state of the projection optical system based on the information,
in projecting the substrate, radiating obliquely incident light to the exposure apparatus inspection mask from a direction offset by a first angle from a vertical direction.

6. The method of inspecting an exposure apparatus according to claim 5, wherein the exposure apparatus comprises:
a mask stage on which the exposure apparatus inspection mask is placed;
a light source optical system for radiating obliquely incident light to the exposure apparatus inspection mask from a direction offset by a first angle from a vertical direction; and
a projection optical system for projecting the obliquely incident light to a substrate,
the exposure apparatus inspection mask comprises:
a transparent substrate;
semi-transparent attenuated films selectively and periodically disposed on the transparent substrate at a predetermined pitch; and
shade films selectively and periodically disposed on the attenuated films at a predetermined pitch,
the attenuated films are formed to have such a thickness that a phase difference between a phase of first light passing through only the transparent substrate and a phase of second light passing through the attenuated films and the transparent substrate is set to a value other than 180°×n (n is an integer equal to or larger than 0).

7. The method of inspecting an exposure apparatus according to claim 6, wherein the following expression is satisfied when an exposure wavelength is shown by λ, the numerical aperture of the projection optical system is shown by NA, the pitch is shown by p, the distance from the center of a pupil of the projection optical system to the center of an illumination pole is shown by σ_{c}, and the radius of the illumination pole is shown by σᵣ:
$$\frac{λ}{2 {σ}_{c} \cdot NA} < p < \frac{2 λ}{NA ( {σ}_{c} + {σ}_{r} + 1 )}$$

8. The method of inspecting an exposure apparatus according to claim 5, wherein the state of the projection optical system is a thermal aberration parameter.

9. An exposure apparatus inspection mask having asymmetric diffraction grating regions for generating +1-order diffracted light and −1-order diffracted light having a different diffraction efficiency,
each of the asymmetric diffraction grating regions comprising:
a reflecting substrate;
phase shifter films selectively and periodically disposed on the reflecting substrate at a predetermined pitch, having reflectivity to irradiated light which is lower than one of the reflecting substrate; and
absorption films selectively and periodically disposed on the phase shifter films at a predetermined pitch, and
the phase shifter films are formed to have such a thickness that a phase difference between a phase of first light reflecting only the reflecting substrate and a phase of second light reflecting only the phase shifter films is set to a value other than 180°×n (n is an integer equal to or larger than 0).

10. The exposure apparatus inspection mask according to claim 9, wherein when the length of the predetermined pitch is shown by p, the length in the pitch direction of the regions in which the phase shifter films are exposed to a surface is shown by a, the length in the pitch direction of the regions in which the reflecting substrate is exposed to the surface is shown by b, the phase difference is shown by φ, the amplitude reflectivity of the phase shifter films is shown by t, α=a/p, and β=b/p, the following expressions are satisfied.
$$t = \sqrt{\frac{{sin}^{2} ( πβ )}{{sin}^{2} ( πα )}}$$
$$φ = \pm \frac{π}{2} ( α + β )$$

11. The exposure apparatus inspection mask according to claim 9, wherein
four sets of the asymmetric diffraction grating regions are disposed so that they are arranged in a predetermined direction,
the first asymmetric diffraction grating region is in the relation of mirror symmetry to the second asymmetric diffraction grating region, and
the third asymmetric diffraction grating region is in the relation of mirror symmetry to the fourth asymmetric diffraction grating region.

12. The exposure apparatus inspection mask according to claim 9, wherein
each of the reflecting substrate and the phase shifter films comprise multilayer film which alternately accumulated molybdenum and silicon,
the phase shifters comprise tantalum nitride.
